(19) United States
(12) Patent Application Publication
(10) Pub. No.: US 2020/0067398 A1
(43) Pub. Date: Feb. 27, 2020

(54) Magnet generator having superconductor simulators

(71) Applicant: Dunfu Lu, Denver, CO (US)

(72) Inventor: Dunfu Lu, Denver, CO (US)

(21) Appl. No.: 16/664,971

(22) Filed: Oct. 28, 2019

(51) Int. Cl. H02K 55/04; H01L 39/02; H01L 39/14

(52) U.S. Cl. CPC H02K 55/04; H01L 39/14; H01L 39/02

(57) ABSTRACT

A permanent magnet generator includes a source of electrical energy; a superconductor simulator assembly electrically connected to the source of electrical energy; a plurality of armature windings; a rotor winding energized by the superconductor simulator assembly for generating electricity in the armature windings; and a feedback device for returning a portion of the generated electricity to the source of electrical energy.

### BACKGROUND OF THE INVENTION

### 1. Field of the Invention

The invention relates to electricity generation and more particularly to a magnet generator having a plurality of superconductor simulators for increasing voltage and current inputs.

### 2. Description of Related Art

Energy forms include oil, coal, natural gas, nuclear, hydro, magnets and renewables. For a permanent magnet generator, the excitation field is provided by a permanent magnet in the rotor instead of a coil in which the rotor and magnetic field rotate with the same speed because the magnetic field is generated through a shaft mounted permanent magnet mechanism and current is induced into the stationary armature. Conventionally, superconductors are used to activate the rotor for generating electricity. There are high-temperature conductors. However, superconductors are hard to obtain in room temperature. Thus, the need for improvement still exists.

### SUMMARY OF THE INVENTION

It is therefore one object of the invention to provide an electric generator comprising a source of electrical energy; a superconductor simulator assembly electrically connected to the source of electrical energy; a plurality of armature windings; and a rotor winding energized by the superconductor simulator assembly for generating electricity in the armature windings.

The above and other objects, features and advantages of the invention will become apparent from the following detailed description taken with the accompanying drawings.

### BRIEF DESCRIPTION OF THE DRAWINGS

FIG. 1 is a block diagram of a magnet generator according to the invention; and

FIG. 2 is a block diagram of the superconductor simulator assembly.

### DETAILED DESCRIPTION OF THE INVENTION

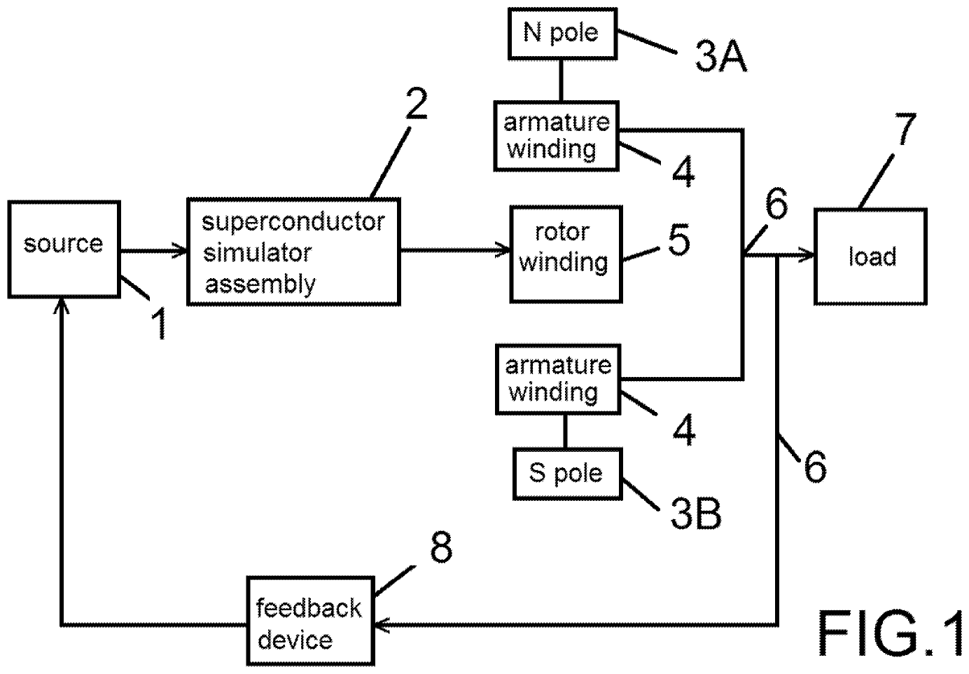

Referring to FIG. 1, a magnet generator in accordance with the invention comprises a source of electrical energy 1 (e.g., batteries or mains electricity); a superconductor simulator assembly 2 electrically connected to the source of electrical energy 1; a N pole 3A of a magnet (e.g., permanent magnet); a S pole 3B of the magnet; two armature windings 4 mounted with the N pole 3A and the S pole 3B respectively; a rotor winding 5 energized by the superconductor simulator assembly 2 for generating electricity in the armature windings 4 by changing its magnetic flux; a load 7; wires 6 for supplying electricity from the armature windings 4 to the load 7; and a feedback device 8 for returning a portion of the generated electricity to the source of electrical energy 1 by means of the wires 6.

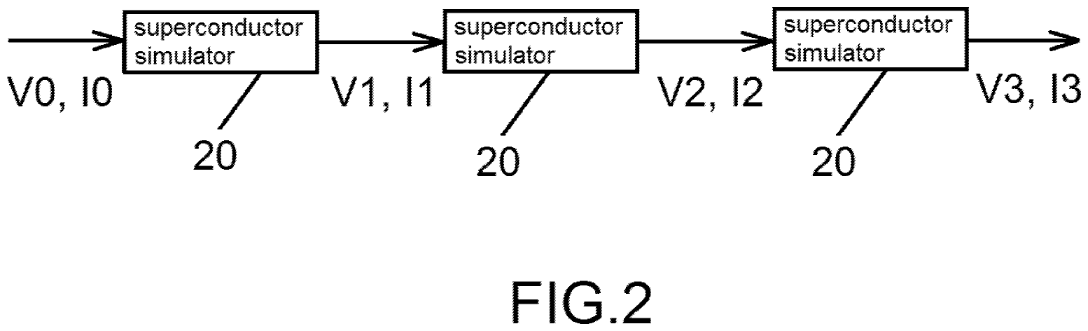

Referring to FIG. 2 in conjunction with FIG. 1, the superconductor simulator assembly 2 includes a plurality of superconductor simulators 20 connected in series. Each superconductor simulator 20 is formed of a metal tube filled with filling material and a sleeve disposed on the metal tube and has a metal coating formed by electroplating. As shown, a first input of V0, I0 is supplied to a first superconductor simulator 20. The first input is amplified by the first superconductor simulator 20 to generate an output (or second input) of V1, I1 greater than the first input of V0, I0. And in turn, the second input is amplified by a second superconductor simulator 20 to generate an output (or third input) of V2, I2 greater than the second input of V1, 11. Finally, the third input is amplified by a third superconductor simulator 20 to generate an output of V3, I3 greater than the second input of V2, I2.

Alternatively, the superconductor simulator assembly 2 is unitary in other embodiments.

While the invention has been described in terms of preferred embodiments, those skilled in the art will recognize that the invention can be practiced with modifications within the spirit and scope of the appended claims.

What is claimed is:

1. An electric generator, comprising:
a source of electrical energy;
a superconductor simulator assembly electrically connected to the source of electrical energy;
a plurality of armature windings; and
a rotor winding energized by the superconductor simulator assembly for generating electricity in the armature windings.

2. The electric generator of claim 1, further comprising a feedback device for returning a portion of the generated electricity to the source of electrical energy.

3. The electric generator of claim 1, wherein the superconductor simulator assembly includes a plurality of superconductor simulators connected in series.

4. The electric generator of claim 3, wherein each superconductor simulator is formed of a metal tube filled with filling material and a sleeve disposed on the metal tube, and has a metal coating.
